(19) United States
(12) Patent Application Publication
(10) Pub. No.: US 2024/0071483 A1
(43) Pub. Date: Feb. 29, 2024

(54) DRIFT CORRECTION IN SLC AND MLC MEMORY DEVICES

(71) Applicant: Micron Technology, Inc., Boise, ID (US)

(72) Inventors: Christophe Vincent Antoine Laurent, Agrate Brianza (MB) (IT); Francesco Mastroianni, Melzo (MI) (IT); Andrea Martinelli, Bergamo (BG) (IT); Efrem Bolandrina, Fiorano al Serio (BG) (IT); Lucia Di Martino, Monza (MB) (IT); Riccardo Muzzetto, Arcore (MB) (IT); Zhongyuan Lu, Boise, ID (US); Karthik Sarpatwari, Boise, ID (US); Nevil N. Gajera, Meridian, ID (US)

(21) Appl. No.: 17/898,392

(22) Filed: Aug. 29, 2022

(51) Int. Cl. G11C 11/56; G06F 3/06; G06F 12/02

(52) U.S. Cl. CPC G11C 11/5628; G06F 3/0679; G06F 12/0246

(57) ABSTRACT

Disclosed are techniques for correcting drift accumulation in memory cells. In some aspects, the techniques described herein relate to a memory device including: a memory array, the memory array including a set of memory cells; and a memory controller configured to read data from the memory array, the memory controller configured to: sense a first distribution of the set of memory cells, detect a missing cell in the first distribution, increase a voltage on the missing cell causing the missing cell to be read as part of the first distribution, detect that a second memory cell in a second distribution was read while sensing the first distribution, and mask the second memory cell and mark the second memory cell as belonging to the second distribution.

### FIELD OF THE TECHNOLOGY

At least some embodiments disclosed herein relate generally to memory devices (e.g., semiconductor memory devices) and, in particular, to improvements in error correction in such memory devices.

### BACKGROUND

Memory devices store data in cells that can store two or more states. Such cells are associated with threshold (“turn on”) voltages. If a sense or read voltage is applied below the threshold voltage, a cell does not conduct. If a read voltage is higher than the threshold voltage, the cell conducts. In certain memories, a two-stage bipolar read can be performed such that a positive read voltage and a negative voltage are sequentially applied to read data from a distribution of cells. During the life of a cell, its voltage threshold may change or shift, thus affecting its read performance. Excessive drift can cause a memory cell to not conduct when appropriate or conduct when inappropriate, resulting in errors in read operations.

### BRIEF DESCRIPTION OF THE DRAWINGS

FIG. 1 illustrates an example memory array in accordance with various embodiments of the present disclosure.

FIG. 2 is a diagram illustrating a voltage threshold drift of a single-level cell (SLC) memory device.

FIGS. 3A through 3C are diagrams illustrating voltage threshold drifts of a multi-level cell (MLC) memory device.

FIG. 4 is a flow diagram illustrating a method for performing drift cancellation during an access operation according to some of the example embodiments.

FIG. 5 is a flow diagram illustrating a method for performing drift cancellation during an access operation according to some of the example embodiments.

FIG. 6 is a block diagram illustrating a computing system according to some embodiments of the disclosure.

FIG. 7 is a block diagram of a computing device according to some embodiments of the disclosure.

### DETAILED DESCRIPTION

In a semiconductor memory device (e.g., SLC or MLC), an error correction code (ECC) engine can be used to ensure that all the cells of a lower distribution or state are snapped during a read operation to avoid drift accumulation as well to avoid error accumulation in MLCs between first and second read phases. Some embodiments use an ECC engine embedded during the read operation (both after the first phase and, in MLC memory implementations, the second phase) to identify the erroneous cells and apply a special treatment to them to avoid drift accumulation, avoid error accumulation, and reduce the number of digital to analog conversion (DAC) steps in case of cells miscount.

For SLC embodiments, memory cells have a natural drift that tends to raise the threshold voltage (Vₜₕ) of each cell. This drift effect is canceled every time a cell is snapped. As used herein, snapping a memory cell refers to switching a cell on such that current is flowing through the cell for a short time which causes a change in the voltage threshold of the cell. During a read operation of SLC cells, the cells from the low distribution (e.g., binary one state) are snapped, and thus their drift is canceled. However, if some cells are not snapped (erroneously) due to a drift in Vₜₕ, their drift will not be canceled, and they will continue to drift to higher and higher levels.

The foregoing effect also applies to MLC memories. If a cell from a first state (e.g., set distribution) is not snapped during a first read phase, its drift is not canceled. As in the SLC embodiments, if too many cells are read during the first read phase, some cells of the second state (e.g., reset distribution) may be deactivated after the first read phase. In the various embodiments, a memory controller is configured to count until a predetermined quantity of cells is read in response to a positive polarity read voltage, and thus the target count will not be reached, and the DAC operations will rise until the Vₘₐₓ, with an increased risk of intercepting cells from the third state (e.g., ternary distribution).

The example embodiments remedy these and other similar problems in the start of the art.

In some aspects, the techniques described herein relate to a memory device including: a memory array, the memory array including a set of memory cells; and a memory controller configured to read data from the memory array, the memory controller configured to: sense a first distribution of the set of memory cells, detect a missing cell in the first distribution using an ECC engine, increase a voltage on the missing cell causing the missing cell to be read as part of the first distribution, detect that a second memory cell in a second distribution was read while sensing the first distribution using the ECC engine, and mask the second memory cell and mark the second memory cell as belonging to the second distribution.

In some aspects, the techniques described herein relate to a memory device, wherein sensing a first distribution includes applying a positive read voltage to the set of memory cells and sensing a subset of the set of memory cells that conduct.

In some aspects, the techniques described herein relate to a memory device, wherein the set of memory cells includes single-level cell memory cells.

In some aspects, the techniques described herein relate to a memory device, wherein the first distribution includes a binary one state. In other impls, the first distribution may include a binary zero state and the choice is non-limiting.

In some aspects, the techniques described herein relate to a memory device, wherein the set of memory cells includes multi-level cell (MLC) memory cells.

In some aspects, the techniques described herein relate to a memory device, the memory controller further configured to: sense a second distribution of the set of memory cells; detect a second missing cell in the second distribution via the ECC engine; and increase a voltage on the second missing cell causing the second missing cell to be read as part of the second distribution.

In some aspects, the techniques described herein relate to a memory device, wherein sensing a second distribution includes applying a negative read voltage to the set of memory cells and sensing a subset of the set of memory cells that conduct.

In some aspects, the techniques described herein relate to a memory device, wherein the first distribution includes a set state second distribution and a reset state distribution.

In some aspects, the techniques described herein relate to a memory device, wherein detecting a missing cell in the first distribution includes applying an error correction code (ECC) to the first distribution.

In some aspects, the techniques described herein relate to a memory device, wherein the set of memory cells include chalcogenide-based memory cells.

In some aspects, the techniques described herein relate to a method including: sensing a first distribution of a set of memory cells, detecting a missing cell in the first distribution, increasing a voltage on the missing cell causing the missing cell to be read as part of the first distribution, detecting that a second memory cell in a second distribution was read while sensing the first distribution, and masking the second memory cell and mark the second memory cell as belonging to the second distribution.

In some aspects, the techniques described herein relate to a method, wherein sensing a first distribution includes applying a positive read voltage to the set of memory cells and sensing a subset of the set of memory cells that conduct.

In some aspects, the techniques described herein relate to a method, wherein the set of memory cells includes single-level cell memory cells.

In some aspects, the techniques described herein relate to a method, wherein the set of memory cells includes multi-level cell (MLC) memory cells.

In some aspects, the techniques described herein relate to a method, further including: sensing a second distribution of the set of memory cells; detecting a second missing cell in the second distribution; and increasing a voltage on the second missing cell causing the second missing cell to be read as part of the second distribution.

In some aspects, the techniques described herein relate to a method, wherein sensing a second distribution includes applying a negative read voltage to the set of memory cells and sensing a subset of the set of memory cells that conduct.

In some aspects, the techniques described herein relate to a method, wherein detecting a missing cell in the first distribution includes applying an error correction code (ECC) to the first distribution.

In some aspects, the techniques described herein relate to a memory device including: a memory array, the memory array including a set of memory cells; and a memory controller configured to read data from the memory array, the memory controller configured to: performing a bipolar read of a portion of the memory array, detecting at least one error using an error correction code (ECC) engine, masking at least one snapped memory cell, and applying a read retry using a negative polarity read voltage.

In some aspects, the techniques described herein relate to a memory device, wherein masking at least one snapped memory cell include masking a first memory cell snapped during a first stage of the bipolar read and a second memory cell snapped during a second stage of the bipolar read.

In some aspects, the techniques described herein relate to a memory device, wherein the at least one error occurred during a negative polarity read performed during the bipolar read, and the memory controller further configured to: mask at least one additional snapped memory cell; and apply a second read retry using a positive polarity read voltage.

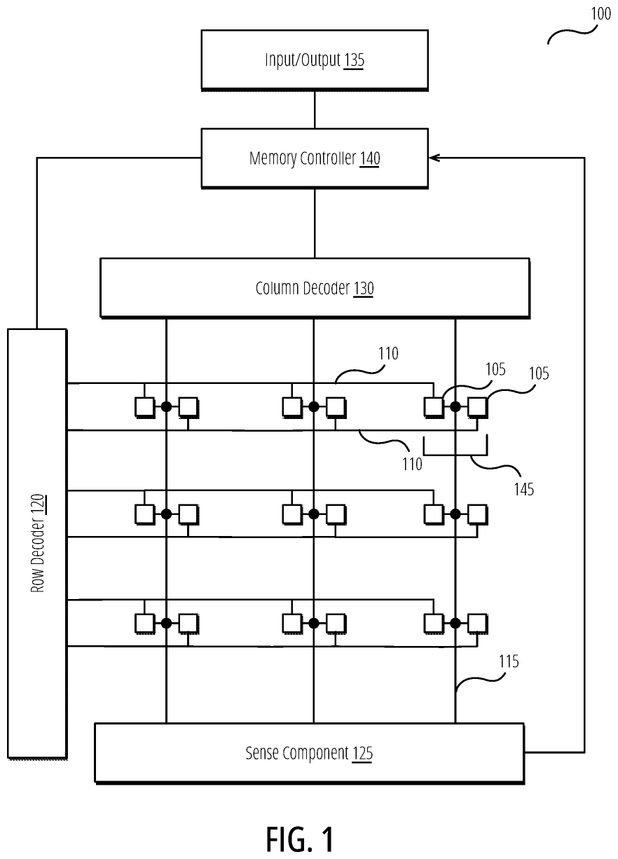

FIG. 1 illustrates an example memory array 100 in accordance with various embodiments of the present disclosure.

Memory array 100 may also be referred to as an electronic memory apparatus. Memory array 100 includes memory cells 105 that are programmable to store different states. Each memory cell 105 may be programmable to store two states, denoted a logic 0 and a logic 1. In some cases, memory cell 105 is configured to store more than two logic states. A memory cell 105 may store a charge representative of the programmable states in a capacitor; for example, a charged and uncharged capacitor may represent two logic states, respectively. DRAM architectures may commonly use such a design, and the capacitor employed may include a dielectric material with linear or paraelectric electric polarization properties as the insulator. By contrast, a ferroelectric memory cell may include a capacitor with a ferroelectric as the insulating material. Different levels of charge of a ferroelectric capacitor may represent different logic states. Ferroelectric materials have non-linear polarization properties; some details and advantages of a ferroelectric memory cell 105 are discussed below.

Memory array 100 may be a three-dimensional (3D) memory array, where two-dimensional (2D) memory arrays are formed on top of one another. This may increase the number of memory cells that may be formed on a single die or substrate as compared with 2D arrays, which in turn may reduce production costs or increase the performance of the memory array, or both. According to the example depicted in FIG. 1, memory array 100 includes two levels of memory cells 105 and may thus be considered a three-dimensional memory array; however, the number of levels is not limited to two. Each level may be aligned or positioned so that memory cells 105 may be approximately aligned with one another across each level, forming a memory cell stack 145.

In some embodiments, memory cells 105 can comprise a chalcogenide-based memory cells that are arranged with other such memory cells in a three-dimensional (3D) architecture, such as a cross-point architecture, or arranged in a three-dimensional (3D) vertical architecture. Cross-point memory (e.g., 3D XPoint memory) uses an array of non-volatile memory cells. The memory cells in cross-point memory are transistor-less. Each of such memory cells can have a selector device and optionally a phase-change memory device that are stacked together as a column in an integrated circuit. Memory cells of such columns are connected in the integrated circuit via two layers of wires running in directions that are perpendicular to each other. One of the two layers is above the memory cells and the other layer is below the memory cells. Thus, each memory cell can be individually selected at a cross point of two wires running in different directions in two layers. Crosspoint memory devices are fast and non-volatile and can be used as a unified memory pool for processing and storage.

In some implementations, the cross point memory uses a memory cell that has an element (e.g., a sole element) acting both as a selector device and a memory device. For example, the memory cell can use a single piece of alloy with variable threshold capability. The read/write operations of such a memory cell can be based on thresholding the memory cell while inhibiting other cells in sub-threshold bias, in a way similar to the read/write operations for a memory cell having a first element acting as a selector device and a second element acting as a phase-change memory device that are stacked together as a column. A selector device usable to store information can be referred to as a selector/memory device.

Such a self-selecting memory cell, having a selector/memory device, can be programmed in cross point memory to have a threshold voltage window. The threshold voltage window can be created by applying programming pulses with opposite polarity to the selector/memory device. For example, the memory cell can be biased to have a positive voltage difference between two sides of the selector/memory device and alternatively, or to have a negative voltage difference between the same two sides of the selector/memory device. When the positive voltage difference is considered in positive polarity, the negative voltage difference is considered in negative polarity that is opposite to the positive polarity. Reading can be performed with a given/fixed polarity. When programmed, the memory cell has a low threshold (e.g., lower than the cell that has been reset, or a cell that has been programmed to have a high threshold), such that during a read operation, the read voltage can cause a programmed cell to snap and thus become conductive while a reset cell remains non-conductive.

Each row of memory cells 105 is connected to an access line 110, and each column of memory cells 105 is connected to a bit line 115. Access lines 110 may also be known as word lines 110, and bit lines 115 may also be known digit lines 115. References to word lines and bit lines, or their analogues, are interchangeable without loss of understanding or operation. Word lines 110 and bit lines 115 may be substantially perpendicular to one another to create an array. As shown in FIG. 1, the two memory cells 105 in a memory cell stack 145 may share a common conductive line such as a digit line 115. That is, a digit line 115 may be in electronic communication with the bottom electrode of the upper memory cell 105 and the top electrode of the lower memory cell 105. Other configurations may be possible, for example, a third layer may share a word line 110 with a lower layer. In general, one memory cell 105 may be located at the intersection of two conductive lines such as a word line 110 and a bit line 115. This intersection may be referred to as a memory cell's address. A target memory cell 105 may be a memory cell 105 located at the intersection of an energized word line 110 and bit line 115; that is, a word line 110 and bit line 115 may be energized in order to read or write a memory cell 105 at their intersection. Other memory cells 105 that are in electronic communication with (e.g., connected to) the same word line 110 or bit line 115 may be referred to as untargeted memory cells 105.

As discussed above, electrodes may be coupled to a memory cell 105 and a word line 110 or a bit line 115. The term electrode may refer to an electrical conductor, and in some cases, may be employed as an electrical contact to a memory cell 105. An electrode may include a trace, wire, conductive line, conductive layer, or the like that provides a conductive path between elements or components of memory array 100.

Operations such as reading and writing may be performed on memory cells 105 by activating or selecting a word line 110 and bit line 115, which may include applying a voltage or a current to the respective line. Word lines 110 and bit lines 115 may be made of conductive materials, such as metals (e.g., copper (Cu), aluminum (Al), gold (Au), tungsten (W), titanium (Ti), etc.), metal alloys, carbon, conductively-doped semiconductors, or other conductive materials, alloys, or compounds. Accessing a target memory cell 105 may affect untargeted memory cells 105. For example, a non-zero voltage may develop across one or more electrodes of the untargeted memory cell 105. By repeatedly energizing the same word line 110 or bit line 115, the effect may compound such that it may corrupt the stored logic values of the untargeted memory cells 105. Methods disclosed herein may prevent such corruption of untargeted memory cells 105. For example, a discharge pulse may be applied to the word line 110 or bit line 115 after an access operation, where the discharge voltage has a polarity opposite the polarity of the access voltage. In other cases, a delay may be instituted before a subsequent access operation to allow the untargeted memory cell 105 to discharge from the previous access operation.

Accessing memory cells 105 may be controlled through a row decoder 120 and a column decoder 130. For example, a row decoder 120 may receive a row address from the memory controller 140 and activate the appropriate word line 110 based on the received row address. Similarly, a column decoder 130 receives a column address from the memory controller 140 and activates the appropriate bit line 115. Thus, by activating a word line 110 and a bit line 115, a memory cell 105 may be accessed.

Upon accessing, a memory cell 105 may be read, or sensed, by sense component 125 to determine the stored state of the memory cell 105. For example, after accessing the memory cell 105, the ferroelectric capacitor of memory cell 105 may discharge onto its corresponding digit line 115. Discharging the ferroelectric capacitor may result from biasing, or applying a voltage, to the ferroelectric capacitor. The discharging may cause a change in the voltage of the digit line 115, which sense component 125 may compare to a reference voltage (not shown) in order to determine the stored state of the memory cell 105. For example, if digit line 115 has a higher voltage than the reference voltage, then sense component 125 may determine that the stored state in memory cell 105 was a logic 1 and vice versa. Sense component 125 may include various transistors or amplifiers in order to detect and amplify a difference in the signals, which may be referred to as latching. The detected logic state of memory cell 105 may then be output through column decoder 130 as input/output 135. In some cases, sense component 125 may be a part of column decoder 130 or row decoder 120. Or, sense component 125 may be connected to or in electronic communication with column decoder 130 or row decoder 120.

A memory cell 105 may be set, or written, by similarly activating the relevant word line 110 and bit line 115—i.e., a logic value may be stored in the memory cell 105. Column decoder 130 or row decoder 120 may accept data, for example input/output 135, to be written to the memory cells 105. A ferroelectric memory cell 105 may be written by applying a voltage across the ferroelectric capacitor. Reading or writing a target memory cell 105 may, however, corrupt the logic states of untargeted memory cells 105. This process is discussed in more detail below.

Some memory architectures, including DRAM, may lose their stored state over time unless they are periodically refreshed by an external power source. For example, a charged capacitor may become discharged over time through leakage currents, resulting in the loss of the stored information. The refresh rate of these so-called volatile memory devices may be relatively high, e.g., tens of refresh operations per second for DRAM arrays, which may result in significant power consumption. With increasingly larger memory arrays, increased power consumption may inhibit the deployment or operation of memory arrays (e.g., power supplies, heat generation, material limits, etc.), especially for mobile devices that rely on a finite power source, such as a battery. As discussed below, ferroelectric memory cells 105 may have beneficial properties that may result in improved performance relative to other memory architectures.

The memory controller 140 may control the operation (read, write, re-write, refresh, discharge, etc.) of memory cells 105 through the various components, for example, row decoder 120, column decoder 130, and sense component 125. In some cases, one or more of the row decoder 120, column decoder 130, and sense component 125 may be co-located with the memory controller 140. Memory controller 140 may generate row and column address signals in order to activate the desired word line 110 and bit line 115. Memory controller 140 may also generate and control various voltage potentials or currents used during the operation of memory array 100. For example, it may apply discharge voltages to a word line 110 or bit line 115 after accessing one or more memory cells 105. In general, the amplitude, shape, or duration of an applied voltage or current discussed herein may be adjusted or varied and may be different for the various operations discussed in operating memory array 100. Furthermore, one, multiple, or all memory cells 105 within memory array 100 may be accessed simultaneously; for example, multiple or all cells of memory array 100 may be accessed simultaneously during a reset operation in which all memory cells 105, or a group of memory cells 105, are set to a single logic state.

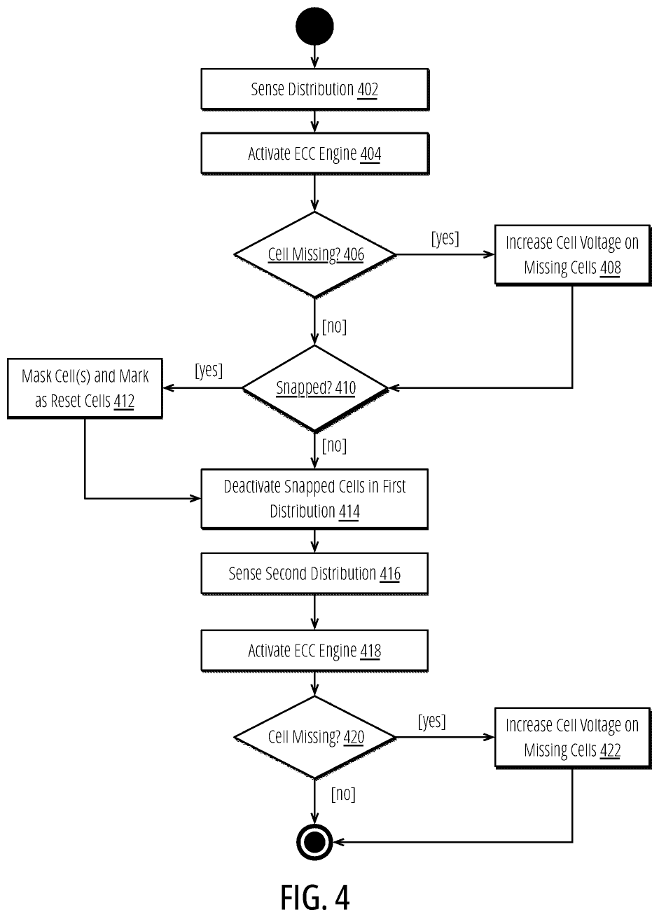

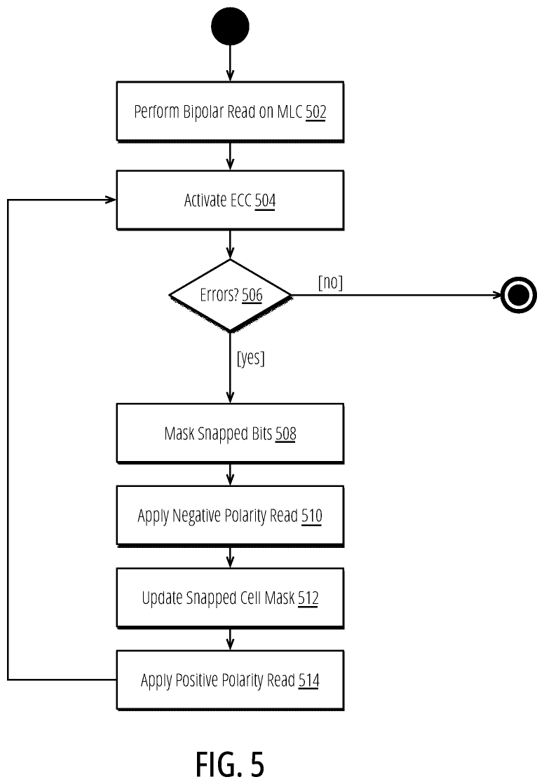

In some embodiments, the memory controller 140 can include a counter that counts the number of expected cells in each distribution. For example, in an SLC memory, the counter can manage expected number of ‘0’ cells and ‘1’ cells. In some embodiments, this counter can be updated during each write operation. Further, in some embodiments, the memory controller 140 can include an ECC engine that can verify codewords read from the memory. The ECC engine can comprise a hard encoder/decoder (e.g., Reed-Solomon) or a soft encoder/decoder (e.g., low density parity check). Finally, the memory controller 140 can comprise a drift correction circuit or logic that can perform the operations of FIG. 4 or 5 as described herein.

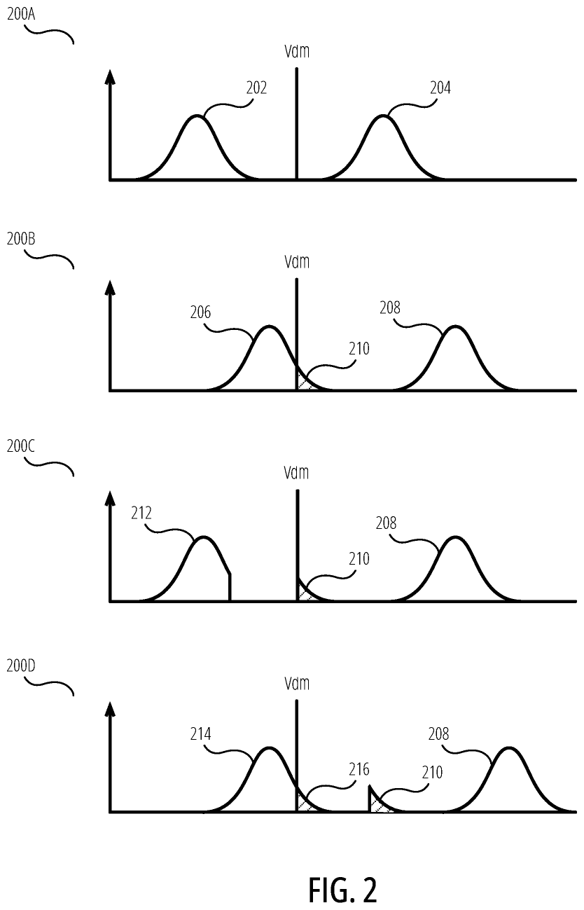

FIG. 2 is a diagram illustrating a voltage threshold drift of a single-level cell (SLC) memory device.

Graph 200A illustrates a two-state voltage distribution of an SLC cell. As illustrated, a low distribution 202 and a high distribution 204 represent the two states (binary one and zero) of the SLC memory cell. As illustrated, these two distributions are below and above an applied read voltage (V_{dm}). The specific voltage ranges of each distribution are not limiting, and any such range represented by the curves of low distribution 202 and a high distribution 204 may be used. Further, the low distribution 202 and a high distribution 204 are separated by a distance, generally referred to as the margin.

As illustrated in graph 200A, when a given SLC cell is read, the read voltage is applied to the gates of each cell in the low distribution 202 and a high distribution 204. Thus, any cells in low distribution 202 are “turned on” since the read voltage is above the voltage thresholds of the low distribution 202 while the cells in high distribution 204 are “turned off” since the read voltage is below the voltage thresholds of the high distribution 204. Thus, a read resulting in an output voltage falling within the low distribution 202 is interpreted as storing a binary zero value, while an output voltage falling within high distribution 204 is interpreted as storing a binary one value.

Graph 200B illustrates a drift in the voltage threshold of the SLC cells after a finite period of time. During a typical programming operation of memory cells (e.g., a block) with user data, some additional memory cells are programmed to a known one of the potential data states. Over time, the threshold voltages programmed in memory cells, including the reference cells, may shift (e.g., drift) by some amount. As illustrated, the low distribution 206 and high distribution 208 both shift higher by some non-limiting amount. However, a portion 210 of the low distribution 206 exceeds the applied read voltage and thus will be read as a binary zero (instead of a binary one), resulting in a corrupted codeword that includes cells in portion 210.

Graph 200C illustrates the threshold voltage distributions after or during an access operation (e.g., read operation).

In some embodiments, an access operation on a memory cell comprising a chalcogenide material can be described as including multiple events, including a thresholding event. When a bias is applied across a memory cell for a certain period, the memory cell comprising the chalcogenide material can undergo a thresholding event, characterized by a rapid increase in the amount of current flow through the memory cell and a “snapback” event, characterized by a rapid reduction in the bias across the memory cell. Once thresholded, the memory cell conducts a relatively large amount of current. Further detail on snapback events can be found in commonly owned U.S. Pat. No. 10,360,975, which is incorporated herein in its entirety.

In the illustrated graph 200C, a read operation is performed that results in a snapback event with respect to low distribution 206. Notably, however, portion 210, having a threshold voltage above the read voltage, is not snapped back since it is (erroneously) not read. As such, portion 212 of the low distribution returns to a valid binary one state (with a valid voltage threshold) while portion 210 remains invalidly in the binary zero state.

In graph 200D, the drift accumulates further as time progresses. First, portion 210 continues to drift higher and higher since it is not “snapped” during the read operation. Further, an additional portion 216 is now excluded from further snapping, similar to portion 210 as discussed. As such, the low distribution 214 continues to shrink as portions (e.g., portion 210 and portion 212) are “broken off” above the read voltage. In the illustrated figures, high distribution 208 may continue to drift higher in an SLC scenario since such drift does not impact the read performance of the cell (in other embodiments, the high distribution 208 may also be snapped).

Thus, in the illustrated graphs, snapping reverts some of the low distribution back to a valid state. However, those portions that have already surpassed read voltage are not snapped since they are not read as invalid low distribution cells (but rather as high distribution cells). As such, this smaller portion of cells will continue to drift. While the graphs of FIG. 2 illustrate SLC memory drift, a similar effect occurs in multi-level cell (MLC) memories and other types of multiple distribution memories, discussed below.

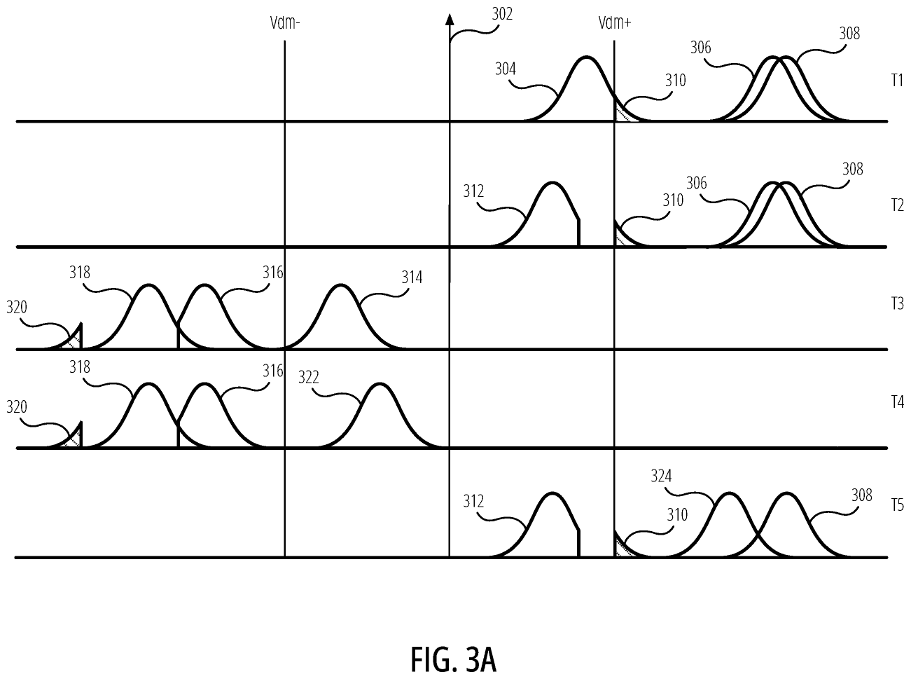

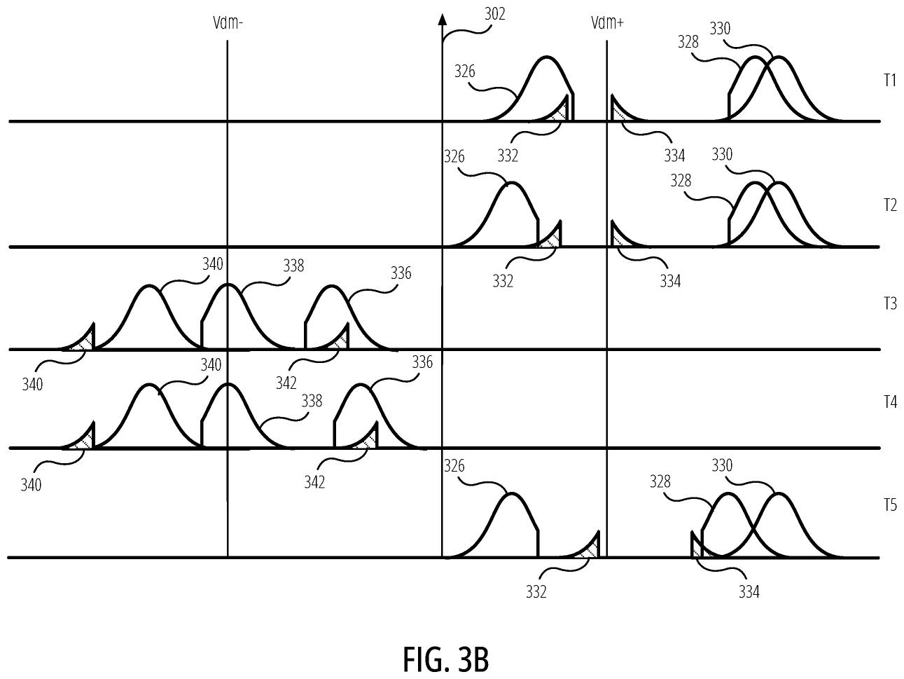

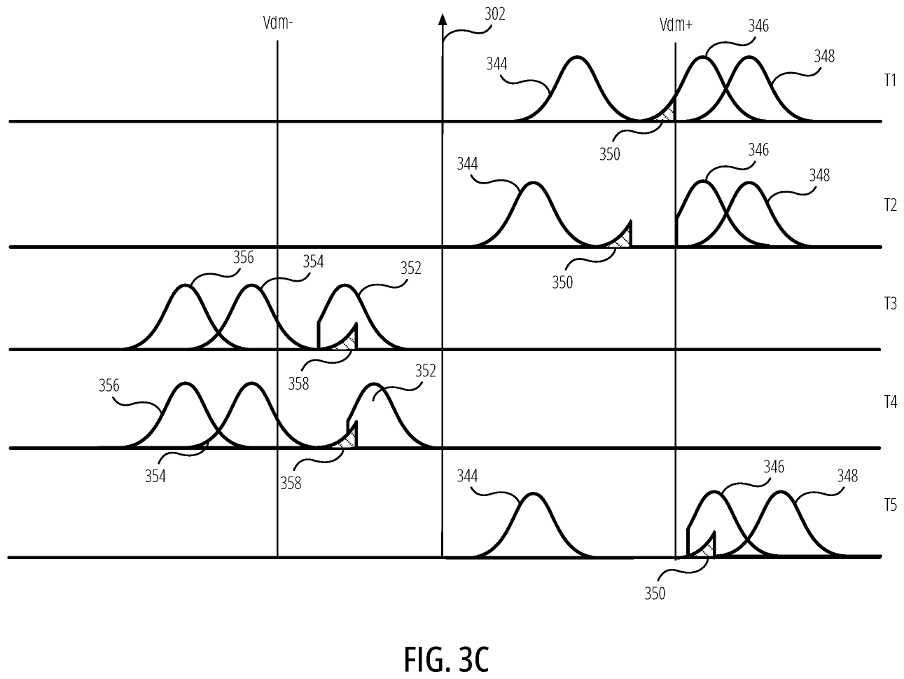

FIG. 3A is a diagram illustrating a voltage threshold drift of an MLC memory device.

The illustrated graphs plot the voltage distributions of cells in a bipolar MLC memory device. In such a device, memory cells are distributed in three states: a set (S) state, reset (R) state, and ternary (T) state. Access operations (e.g., read operations) are performed using a two-stage read process where a positive polarity read voltage (V_{dm}⁺) is first applied and the conducting cells sensed, and a negative polarity read voltage (V_{dm}⁻) is then applied, and the conducting cells are sensed. During the positive polarity read, cells in the set state are closer to the origin 302 (e.g., OV) and thus conduct. During the negative polarity read, these same S state cells are further from the origin 302 and do not conduct. Conversely, during the positive polarity read the reset state cells have a voltage threshold above V_{dm}⁺ and thus do not conduct. However, during the negative polarity read, the R state cells have a threshold voltage above the negative read voltage (V_{dm}⁻) and thus conduct. Thus, R state cells only conduct during negative polarity reads while S state cells only conduct during positive polarity reads. Finally, T state cells have threshold voltages that exceed both read voltages and thus never conduct. Details of normal operations of such a bipolar memory cell (e.g., PCM cell) are described in more detail in commonly-owned U.S. Ser. No. 17/337,806 and are not repeated herein. As will be discussed, threshold drift of multiple distributions may occur in such a state, similar to that discussed in FIG. 2.

At T1 in FIG. 3A, three state distributions are shown: a set state distribution 304, reset state distribution 306, and ternary state distribution 308. These three states may represent three logical states that any given cell in a memory device may be in when sensed (i.e., read). Further, as discussed above reads are performed in two stages by first applying a positive polarity read voltage (V_{dm}⁺) followed by a negative polarity read voltage (V_{dm}⁻). At T1, the threshold voltages of all states have drifted. As discussed, the reset state distribution 306 and ternary state distribution 308 may not be impacted during positive polarity reads since they are not “turned on” as their threshold voltages are above the positive polarity read voltage. By contrast, set state distribution 304 is partially turned on when applying the positive polarity read voltage. Specifically, a portion 310 of the set state distribution 304 is not properly sensed when the positive polarity read voltage is applied. Thus, when a read operation is initiated (i.e., a positive polarity read voltage is applied) in T1, a portion of set state distribution 304 “snaps” back (i.e., its threshold voltage is reverted to a known state) while the portion 310 is not snapped and would continue to drift higher. Such a state is illustrated in T2 where a portion 312 reverts to an expected threshold voltage below the positive polarity read voltage while the portion 310 remains above the positive polarity read voltage.

At T3, a negative polarity read voltage is applied as the second stage of the read operation. Here, three corresponding distributions are illustrated: a negative reset state distribution 314, a negative set state distribution 316, a negative ternary state distribution 318. These three distributions correspond to the sensed output of the corresponding positive polarity distributions when a negative polarity read voltage is applied. As illustrated, since the threshold voltage of set state distribution 304 has drifted, resulting in portion 310 drifting, a corresponding portion 320 has drifted as well. However, in some implementations, the portion 310 and negative set state distribution 316 may be deactivated (e.g., not sensed) in normal operations. Notably, however, since the negative threshold voltage of negative reset state distribution 314 is above the negative read polarity voltage, negative reset state distribution 314 will snap and revert to a higher negative polarity threshold voltage. Specifically, as illustrated in T3, the negative reset state distribution 322 is snapped to an expected range of threshold voltages above the negative polarity read voltage. Additionally, negative set state distribution 316, negative ternary state distribution 318, and corresponding portion 320 are unchanged since they are not snapped during the negative polarity read.

Finally, in T4, the threshold voltage distributions after a read are illustrated. The reset state distribution 324 has “snapped” to its expected threshold voltage range, a portion 312 of the set state voltage range has snapped to its expected threshold voltage range, while a portion 310 of the set state cells has drifted above the positive polarity read voltage. As illustrated, the snapping of the reset state distribution 324 additionally narrows the read window between reset state distribution 324 and portion 310.

In FIG. 3B an additional scenario is presented. In this scenario, three distributions are presented: a set state distribution 326, a reset state distribution 328, and a ternary state distribution 330. Here, a portion 332 of the reset state distribution 328 has drifted below the positive polarity read voltage and thus will be sensed in T1 while a portion 334 of the set state distribution 326 has drifted above the positive polarity read voltage and will not be sensed. After the read in T1, the threshold voltages of both the set state distribution 326 and portion 332 are lowered due to snapping. As such, the portion 332 (of reset state distribution 328 drifts further from reset state distribution 328).

In T3 a negative polarity read voltage is applied. In such a scenario, a negative reset distribution 336, negative set state distribution 338, and negative ternary state distribution 340 corresponding to the set state distribution 326, reset state distribution 328, and ternary state distribution 330, respectively, are illustrated. Further, a portion 342 of the negative set state distribution 338 and a portion 342 of the negative set state distribution 338 are illustrated. As in FIG. 3A, during T3, the negative set state distribution 338 and portion 342 may be deactivated. Further, however, since portion 342 was read (and snapped) during T1 and T2, the portion 342 may also be deactivated. Thus, in T4, the negative reset distribution 336 and portion 342 are shifted (i.e., snapped).

In T5, the state of the memory cells after the two-stage read is illustrated. As illustrated, portion 332 shifts closer to the positive polarity read voltage but is still miscounted as part of set state distribution 326. Further, the portion 332 drifts further from set state distribution 326, resulting in a chronic miscounting.

In FIG. 3C an additional scenario is presented. In this scenario, three distributions are presented: a set state distribution 344, a reset state distribution 346, and a ternary state distribution 348. In T1, a portion 350 of reset state distribution 346 has a threshold voltage below the positive polarity read voltage and is thus sensed during a read in T1, thus overcounting the cells in T1. As such, in T2, the set state distribution 344 and portion 350 snap and their threshold voltages are reduced.

In T3, a negative set state distribution 354, a negative reset state distribution 352, and a negative ternary state distribution 356 corresponding to a set state distribution 344, a reset state distribution 346, and a ternary state distribution 348 are illustrated. Additionally, portion 358 of the negative reset state distribution 356 is illustrated. As in FIG. 3A and FIG. 3B, since the set state distribution 344 was sensed and snapped and the portion 350 was sensed and snapped, the corresponding set state distribution 344 and portion 358 are deactivated during the negative polarity read. As such, the negative reset state distribution 352 is undercounted during T3. Further, during T4, both negative reset state distribution and portion 358 snap. Finally, in T5, portion 350 is raised above the positive polarity read voltage, resulting in a correct count. However, as illustrated, two successive reads in T1 and T5 will return different data.

The foregoing examples are some, not all, of the issues caused due to threshold voltage drift in MLC cells. In general, for both SLC and MLC memory cells, snapping generally provides a “reset” of cell threshold voltages during reads. However, when a cell's threshold voltage passes a read voltage (either in negative or positive polarity), snapping can either not correct the drift or overcorrect the drift, resulting in erratic behavior. The following methods illustrate techniques for correcting such behavior.

FIG. 4 is a flow diagram illustrating a method for performing drift cancellation during an access operation according to some of the example embodiments.

In step 402, method 400 can include sensing a first distribution.

In some embodiments, step 402 can include applying a first read voltage to a plurality of memory cells. In one embodiment, the plurality of memory cells can comprise SLC memory cells. In another embodiment, the plurality of memory cells can comprise MLC memory cells. As discussed, in some embodiments, the MLC memory cells can comprise bipolar MLC memory cells and the first read voltage can comprise a positive read voltage.

Method 400 senses which cells conducted in response to the first read voltage. In an SLC embodiment, these cells may correspond to the low distribution discussed in FIG. 2. In an MLC embodiment, these cells may correspond to the set state cells as discussed in FIGS. 3A through 3C. As a result, method 400 obtains a first distribution of data during the first sensing.

In step 404, method 400 can include activating an error correction code (ECC) engine in response to the first distribution. In general, an ECC engine analyzes the sensed data and detects and/or corrects any errors in the sensed data. In some embodiments, the ECC engine can comprise a hard decoder such as a Reed-Solomon decoder. In other embodiments, the ECC engine can comprise a soft decoder such as a low-density parity check decoder.

In step 406, method 400 can include determining if cells in a first distribution are missing. In an SLC embodiment, the first distribution comprises a low distribution. In an MLC embodiment, the first distribution comprises a set state distribution. In some embodiments, method 400 can employ a count-based algorithm (CBA) to record the expected number of cells in any distribution. That is, upon writing, the CBA can record an expected number of cells. Thus, in step 406, method 400 can determine if the number of sensed cells in the first distribution is equal to the expected number of cells. For example, graph 200A illustrates a scenario where the sensed cells of low distribution 202 will be equal to the expected number of cells while graph 200B illustrates when the number of sensed cells is not equal to what is expected. States T1 and T2 illustrate a similar scenario in the MLC embodiment.

In step 408, method 400 can include increasing the voltage on the missing cells to force such cells to snap and thus revert to an expected threshold voltage. In an embodiment, the missing cells can be determined by analyzing the errors output by the ECC engine during step 404. That is, in the SLC embodiment for example, method 400 can determine which bits (i.e., cells) were sensed in the high distribution that should have been sensed in the low distribution. Method 400 can use the ECC output to select these missing cells and increase the voltage on them until they snap and are properly read.

In step 410, method 400 next determines if any cells in the second distribution (e.g., high distribution in the SLC embodiment, reset state in the MLC embodiment) were snapped. In an embodiment, method 400 again can use the ECC output to determine which cells were improperly sensed in the first distribution to make this determination.

In step 412, method 400 can include masking these cells and, in an MLC embodiment, marking the cells as reset state cells. In the MLC embodiment, in existing scenarios, the snapped cells would be counted as part of the first distribution. As such, in step 412, method 400 corrects this counting by explicitly marking those incorrectly snapped cells as part of the second distribution (e.g., high or reset distributions), thus allowing them to be sensed properly during a negative polarity read operation.

In step 414, method 400 can include deactivating the snapped cells in the first distribution. As discussed, these cells correspond to validly read cells of the first (e.g., low or set) distributions and thus are masked during subsequent reads. Further, due to the explicitly snapping in step 408, the total snapped cells in the first distribution is equal to the expected number of cells sensed.

In step 416, method 400 can include sensing the second distribution. In an MLC embodiment, step 416 can comprise applying a negative polarity read voltage to the memory cells to read the reset state cells, as illustrated in FIGS. 3A through 3C. In an SLC embodiment, the second distribution read may comprise a retry read of the cells.

In step 418, method 400 can re-activate the ECC engine to detect errors in reading, as described previously. In step 420, method 400 can detect if any cells are missing in the second (e.g., high or reset distributions) distribution. If so, method 400 can increase, in step 422, the voltage on these missing cells to force the cells to snap and be read as second distribution cells. Details of this process are similar to that of step 406 and 408 and are not repeated herein.

As illustrated in method 400, an ECC engine is used to correct errors in sensed distributions during read operations. Specifically, method 400 forces snapping of erroneously unsnapped cells and explicitly adjusts cells that erroneously snapped. Method 400 uses the ECC engine which can detect the invalid snapping behavior of cells during read operations to determine which cells to adjust. As a result, uncontrolled drifts of memory cells can be avoided and the memory can function accurately.

FIG. 5 is a flow diagram illustrating a method for performing drift cancellation during an access operation according to some of the example embodiments.

In step 502, method 500 can include performing a bipolar read on an MLC memory device. As discussed above, a bipolar read may include performing a two-stage read wherein a positive polarity read voltage is first applied to MLC memory cells and the resulting values sensed followed by a negative polarity read voltage being applied and the resulting value sensed. In some embodiments, the first sensed values are interpreted as the set state cells while the second values sensed are interpreted as the reset state cells. The remaining unsensed cells are interpreted as the ternary state cells.

In step 504, method 500 can include activating an error correction code (ECC) engine in response to the first distribution. In general, an ECC engine analyzes the sensed data and detects and/or corrects any errors in the sensed data. In some embodiments, the ECC engine can comprise a hard decoder such as a Reed-Solomon decoder. In other embodiments, the ECC engine can comprise a soft decoder such as a low-density parity check decoder.

In step 506, method 500 can include determining if any errors occurred during the read. As discussed above, the ECC engine can identify which cells (e.g., bits) of the read codeword(s) were incorrect, thus signaling which cells were incorrectly read. If no such errors occur, method 500 may end since no errors were present. Alternatively, if at least one cell is incorrectly read, method 500 proceeds to step 508.

In step 508, method 500 can include masking snapped bits.

In general, three scenarios of errors can occur during bipolar reads: errors due to drift in both polarities, in only positive polarity, or in only negative polarity. If errors occurred on both polarities or if the errors only occurred, step 508 can include masking out all the previously snapped bits (i.e., read) in either of positive and negative read stages. Alternatively, if the errors only occur during the positive polarity read, method 500 can optionally mask out all the previously snapped bits (i.e., read) in either of the positive and negative read stages.

In step 510, method 500 can include applying a negative polarity read. In one embodiment, method 500 can include using a CBA to determine which cells (that are not masked) in which to apply a second negative polarity read. In another embodiment, method 500 can include applying a high voltage directly to the cells to perform the negative polarity read. In some embodiments, applying a negative polarity read may be optional if errors only occur during the positive polarity read but may be necessary if the errors occur during the negative polarity read. Notably, in step 510, misread cells in the set state distribution are properly detected and snapped to correct the first set distribution.

In step 512, method 500 can include updating the snapped cell mask. In an embodiment where errors occur on both positive and negative polarity reads or errors occur only on the positive polarity read, step 512 can include masking out all the previously snapped bits (including those set state bits fixed in step 510 as well as the originally snapped bits). Conversely, if errors only occurred on the negative polarity read, step 512 may be optional.

In step 514, method 500 can then apply a read retry by applying a positive polarity voltage to the unmasked cells. In an embodiment where errors occur on both positive and negative polarity reads or errors occur only on the positive polarity read, step 512 can include using a CBA determine which cells (that are not masked) in which to apply a second positive polarity read. In another embodiment, method 500 can include applying a high voltage directly to the cells to perform the second positive polarity read. Conversely, if errors only occurred on the negative polarity read, step 514 may be optional.

After performing the additional reads and masks in the foregoing step, method 500 can then re-check the responsive codeword using the ECC engine in step 504. As illustrated, the process between step 504 and step 514 can be continuously re-executed until a valid codeword is detected. In some embodiments, each iteration improves the read window during retry reads and thus can ultimately result in the correct codeword being read.

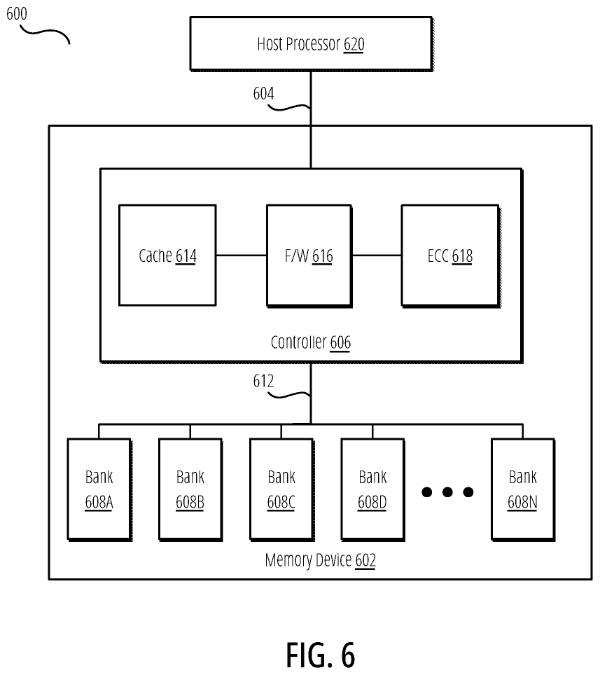

FIG. 6 is a block diagram illustrating a computing system according to some embodiments of the disclosure.

As illustrated in FIG. 6, a computing system 600 includes a host processor 620 communicatively coupled to a memory device 602 via a bus 604. The memory device 602 comprises a controller 606 communicatively coupled to one or more memory banks (e.g., bank 608A, bank 608B, bank 608C, bank 608D, bank 608N, etc.) forming a memory array via an interface 612. As illustrated, the controller 606 includes a local cache 614, firmware 616, and an ECC module 618.

In the illustrated embodiment, host processor 620 can comprise any type of computer processor, such as a central processing unit (CPU), graphics processing unit (GPU), or other types of general-purpose or special-purpose computing devices. The host processor 620 includes one or more output ports that allow for the transmission of address, user, and control data between the host processor 620 and the memory device 602. In the illustrated embodiment, this communication is performed over the bus 604. In one embodiment, the bus 604 comprises an input/output (I/O) bus or a similar type of bus.

The memory device 602 is responsible for managing one or more memory banks (e.g., bank 608A, bank 608B, bank 608C, bank 608D, bank 608N, etc.). In one embodiment, the memory banks (e.g., bank 608A, bank 608B, bank 608C, bank 608D, bank 608N, etc.) comprise NAND Flash dies or other configurations of non-volatile memory. In one embodiment, the memory banks (e.g., bank 608A, bank 608B, bank 608C, bank 608D, bank 608N, etc.) comprise a memory array.

The memory banks (e.g., bank 608A, bank 608B, bank 608C, bank 608D, bank 608N, etc.) are managed by the controller 606. In some embodiments, the controller 606 comprises a computing device configured to mediate access to and from banks (e.g., bank 608A, bank 608B, bank 608C, bank 608D, bank 608N, etc.). In one embodiment, the controller 606 comprises an ASIC or other circuitry installed on a printed circuit board housing the memory banks (e.g., bank 608A, bank 608B, bank 608C, bank 608D, bank 608N, etc.). In some embodiments, the controller 606 may be physically separate from the memory banks (e.g., bank 608A, bank 608B, bank 608C, bank 608D, bank 608N, etc.). The controller 606 communicates with the memory banks (e.g., bank 608A, bank 608B, bank 608C, bank 608D, bank 608N, etc.) over the interface 612. In some embodiments, this interface 612 comprises a physically wired (e.g., traced) interface. In other embodiments, the interface 612 comprises a standard bus for communicating with memory banks (e.g., bank 608A, bank 608B, bank 608C, bank 608D, bank 608N, etc.).

The controller 606 comprises various modules including local cache 614, firmware 616 and ECC module 618. In one embodiment, the various modules (e.g., local cache 614, firmware 616 and ECC module 618) comprise various physically distinct modules or circuits. In other embodiments, the modules (e.g., local cache 614, firmware 616 and ECC module 618) may completely (or partially) be implemented in software or firmware.

As illustrated, firmware 616 comprises the core of the controller and manages all operations of the controller 606. The firmware 616 may implement some or all of the methods described above. Specifically, the firmware 616 may implement the methods described in the foregoing figures.

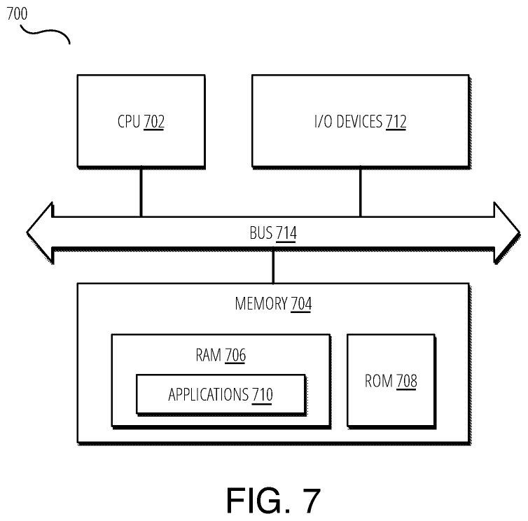

FIG. 7 is a block diagram of a computing device according to some embodiments of the disclosure.

As illustrated, the device 700 includes a processor or central processing unit (CPU) such as CPU 702 in communication with a memory 704 via a bus 714. The device also includes one or more input/output (I/O) or peripheral devices 712. Examples of peripheral devices include, but are not limited to, network interfaces, audio interfaces, display devices, keypads, mice, keyboard, touch screens, illuminators, haptic interfaces, global positioning system (GPS) receivers, cameras, or other optical, thermal, or electromagnetic sensors.

In some embodiments, the CPU 702 may comprise a general-purpose CPU. The CPU 702 may comprise a single-core or multiple-core CPU. The CPU 702 may comprise a system-on-a-chip (SoC) or a similar embedded system. In some embodiments, a graphics processing unit (GPU) may be used in place of, or in combination with, a CPU 702. Memory 704 may comprise a memory system including a dynamic random-access memory (DRAM), static random-access memory (SRAM), Flash (e.g., NAND Flash), or combinations thereof. In one embodiment, the bus 714 may comprise a Peripheral Component Interconnect Express (PCIe) bus. In some embodiments, the bus 714 may comprise multiple busses instead of a single bus.

Memory 704 illustrates an example of a non-transitory computer storage media for the storage of information such as computer-readable instructions, data structures, program modules, or other data. Memory 704 can store a basic input/output system (BIOS) in read-only memory (ROM), such as ROM 708 for controlling the low-level operation of the device. The memory can also store an operating system in random-access memory (RAM) for controlling the operation of the device.

Applications 710 may include computer-executable instructions which, when executed by the device, perform any of the methods (or portions of the methods) described previously in the description of the preceding figures. In some embodiments, the software or programs implementing the method embodiments can be read from a hard disk drive (not illustrated) and temporarily stored in RAM 706 by CPU 702. CPU 702 may then read the software or data from RAM 706, process them, and store them in RAM 706 again.

The device may optionally communicate with a base station (not shown) or directly with another computing device. One or more network interfaces in peripheral devices 712 are sometimes referred to as a transceiver, transceiving device, or network interface card (NIC).

An audio interface in peripheral devices 712 produces and receives audio signals such as the sound of a human voice. For example, an audio interface may be coupled to a speaker and microphone (not shown) to enable telecommunication with others or generate an audio acknowledgment for some action. Displays in peripheral devices 712 may comprise liquid crystal display (LCD), gas plasma, light-emitting diode (LED), or any other type of display device used with a computing device. A display may also include a touch-sensitive screen arranged to receive input from an object such as a stylus or a digit from a human hand.

A keypad in peripheral devices 712 may comprise any input device arranged to receive input from a user. An illuminator in peripheral devices 712 may provide a status indication or provide light. The device can also comprise an input/output interface in peripheral devices 712 for communication with external devices, using communication technologies, such as USB, infrared, Bluetooth®, or the like. A haptic interface in peripheral devices 712 provides tactile feedback to a user of the client device.

A GPS receiver in peripheral devices 712 can determine the physical coordinates of the device on the surface of the Earth, which typically outputs a location as latitude and longitude values. A GPS receiver can also employ other geo-positioning mechanisms, including, but not limited to, triangulation, assisted GPS (AGPS), E-OTD, CI, SAI, ETA, BSS, or the like, to further determine the physical location of the device on the surface of the Earth. In one embodiment, however, the device may communicate through other components, providing other information that may be employed to determine the physical location of the device, including, for example, a media access control (MAC) address, Internet Protocol (IP) address, or the like.

The device may include more or fewer components than those shown in FIG. 7, depending on the deployment or usage of the device. For example, a server computing device, such as a rack-mounted server, may not include audio interfaces, displays, keypads, illuminators, haptic interfaces, Global Positioning System (GPS) receivers, or cameras/sensors. Some devices may include additional components not shown, such as graphics processing unit (GPU) devices, cryptographic co-processors, artificial intelligence (AI) accelerators, or other peripheral devices.

The subject matter disclosed above may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware, or any combination thereof (other than software per se). The preceding detailed description is, therefore, not intended to be taken in a limiting sense.

Throughout the specification and claims, terms may have nuanced meanings suggested or implied in context beyond an explicitly stated meaning. Likewise, the phrase “in an embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

In general, terminology may be understood at least in part from usage in context. For example, terms, such as “and,” “or,” or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

The present disclosure is described with reference to block diagrams and operational illustrations of methods and devices. It is understood that each block of the block diagrams or operational illustrations, and combinations of blocks in the block diagrams or operational illustrations, can be implemented by means of analog or digital hardware and computer program instructions. These computer program instructions can be provided to a processor of a general-purpose computer to alter its function as detailed herein, a special purpose computer, application-specific integrated circuit (ASIC), or other programmable data processing apparatus, such that the instructions, which execute via the processor of the computer or other programmable data processing apparatus, implement the functions/acts specified in the block diagrams or operational block or blocks. In some alternate implementations, the functions or acts noted in the blocks can occur out of the order noted in the operational illustrations. For example, two blocks shown in succession can in fact be executed substantially concurrently or the blocks can sometimes be executed in the reverse order, depending upon the functionality or acts involved.

These computer program instructions can be provided to a processor of a general purpose computer to alter its function to a special purpose; a special purpose computer; ASIC; or other programmable digital data processing apparatus, such that the instructions, which execute via the processor of the computer or other programmable data processing apparatus, implement the functions or acts specified in the block diagrams or operational block or blocks, thereby transforming their functionality in accordance with embodiments herein.

For the purposes of this disclosure a computer readable medium (or computer-readable storage medium) stores computer data, which data can include computer program code or instructions that are executable by a computer, in machine readable form. By way of example, and not limitation, a computer readable medium may comprise computer readable storage media, for tangible or fixed storage of data, or communication media for transient interpretation of code-containing signals. Computer readable storage media, as used herein, refers to physical or tangible storage (as opposed to signals) and includes without limitation volatile and non-volatile, removable, and non-removable media implemented in any method or technology for the tangible storage of information such as computer-readable instructions, data structures, program modules or other data. Computer readable storage media includes, but is not limited to, RAM, ROM, EPROM, EEPROM, flash memory or other solid-state memory technology, CD-ROM, DVD, or other optical storage, magnetic cassettes, magnetic tape, magnetic disk storage or other magnetic storage devices, or any other physical or material medium which can be used to tangibly store the desired information or data or instructions and which can be accessed by a computer or processor.

For the purposes of this disclosure a module is a software, hardware, or firmware (or combinations thereof) system, process or functionality, or component thereof, that performs or facilitates the processes, features, and/or functions described herein (with or without human interaction or augmentation). A module can include sub-modules. Software components of a module may be stored on a computer readable medium for execution by a processor. Modules may be integral to one or more servers or be loaded and executed by one or more servers. One or more modules may be grouped into an engine or an application.

Those skilled in the art will recognize that the methods and systems of the present disclosure may be implemented in many manners and as such are not to be limited by the foregoing exemplary embodiments and examples. In other words, functional elements being performed by single or multiple components, in various combinations of hardware and software or firmware, and individual functions, may be distributed among software applications at either the client level or server level or both. In this regard, any number of the features of the different embodiments described herein may be combined into single or multiple embodiments, and alternate embodiments having fewer than, or more than, all the features described herein are possible.

Functionality may also be, in whole or in part, distributed among multiple components, in manners now known or to become known. Thus, a myriad of software, hardware, and firmware combinations are possible in achieving the functions, features, interfaces, and preferences described herein. Moreover, the scope of the present disclosure covers conventionally known manners for carrying out the described features and functions and interfaces, as well as those variations and modifications that may be made to the hardware or software or firmware components described herein as would be understood by those skilled in the art now and hereafter.

Furthermore, the embodiments of methods presented and described as flowcharts in this disclosure are provided by way of example to provide a more complete understanding of the technology. The disclosed methods are not limited to the operations and logical flow presented herein. Alternative embodiments are contemplated in which the order of the various operations is altered and in which sub-operations described as being part of a larger operation are performed independently.

While various embodiments have been described for purposes of this disclosure, such embodiments should not be deemed to limit the teaching of this disclosure to those embodiments. Various changes and modifications may be made to the elements and operations described above to obtain a result that remains within the scope of the systems and processes described in this disclosure.

What is claimed is:

1. A memory device comprising:
a memory array, the memory array comprising a set of memory cells; and
a memory controller configured to read data from the memory array, the memory controller configured to:
sense a first distribution of the set of memory cells,
detect a missing cell in the first distribution,
increase a voltage on the missing cell causing the missing cell to be read as part of the first distribution,
detect that a second memory cell in a second distribution was read while sensing the first distribution, and
mask the second memory cell and mark the second memory cell as belonging to the second distribution.

2. The memory device of claim 1, wherein sensing a first distribution comprises applying a positive read voltage to the set of memory cells and sensing a subset of the set of memory cells that conduct.

3. The memory device of claim 1, wherein the set of memory cells comprises single-level cell memory cells.

4. The memory device of claim 2, wherein the first distribution comprises either a binary one state or binary zero state.

5. The memory device of claim 1, wherein the set of memory cells comprises multi-level cell (MLC) memory cells.

6. The memory device of claim 5, the memory controller further configured to:
sense a second distribution of the set of memory cells;
detect a second missing cell in the second distribution; and
increase a voltage on the second missing cell causing the second missing cell to be read as part of the second distribution.

7. The memory device of claim 6, wherein sensing a second distribution comprises applying a negative read voltage to the set of memory cells and sensing a subset of the set of memory cells that conduct.

8. The memory device of claim 5, wherein the first distribution comprises a set state second distribution and a reset state distribution.

9. The memory device of claim 1, wherein detecting a missing cell in the first distribution comprises applying an error correction code (ECC) to the first distribution.

10. The memory device of claim 1, wherein the set of memory cells comprise chalcogenide-based memory cells.

11. A method comprising:
sensing a first distribution of a set of memory cells,
detecting a missing cell in the first distribution,
increasing a voltage on the missing cell causing the missing cell to be read as part of the first distribution,
detecting that a second memory cell in a second distribution was read while sensing the first distribution, and
masking the second memory cell and mark the second memory cell as belonging to the second distribution.

12. The method of claim 11, wherein sensing a first distribution comprises applying a positive read voltage to the set of memory cells and sensing a subset of the set of memory cells that conduct.

13. The method of claim 11, wherein the set of memory cells comprises single-level cell memory cells.

14. The method of claim 11, wherein the set of memory cells comprises multi-level cell (MLC) memory cells.

15. The method of claim 14, further comprising:
sensing a second distribution of the set of memory cells;
detecting a second missing cell in the second distribution; and
increasing a voltage on the second missing cell causing the second missing cell to be read as part of the second distribution.

16. The method of claim 15, wherein sensing a second distribution comprises applying a negative read voltage to the set of memory cells and sensing a subset of the set of memory cells that conduct.

17. The method of claim 11, wherein detecting a missing cell in the first distribution comprises applying an error correction code (ECC) to the first distribution.

18. A memory device comprising:
a memory array, the memory array comprising a set of memory cells; and
a memory controller configured to read data from the memory array, the memory controller configured to:
performing a bipolar read of a portion of the memory array,
detecting at least one error using an error correction code (ECC) engine,
masking at least one snapped memory cell, and
applying a read retry using a negative polarity read voltage.

19. The memory device of claim 18, wherein masking at least one snapped memory cell comprise masking a first memory cell snapped during a first stage of the bipolar read and a second memory cell snapped during a second stage of the bipolar read.

20. The memory device of claim 18, wherein the at least one error occurred during a negative polarity read performed during the bipolar read, and the memory controller further configured to:
mask at least one additional snapped memory cell; and
apply a second read retry using a positive polarity read voltage.
